(19) United States
(12) Patent Application Publication
(10) Pub. No.: US 2024/0232477 A1
(43) Pub. Date: Jul. 11, 2024

(54) METHOD FOR PREDICTING PERFORMANCE OF LIGHT-EMITTING DIODE STRUCTURE

(71) Applicants: Xiamen University, Xiamen (CN); TAN KAH KEE INNOVATION LABORATORY, Xiamen (CN)

(72) Inventors: Kai Huang, Xiamen (CN); Ying Jiang, Xiamen (CN); Zhuoying Jiang, Xiamen (CN); Lin Li, Xiamen (CN); Cheng Li, Xiamen (CN); Jinchai Li, Xiamen (CN); Rong Zhang, Xiamen (CN); Junyong Kang, Xiamen (CN)

(21) Appl. No.: 18/616,181

(22) Filed: Mar. 26, 2024

Related U.S. Application Data
(63) Continuation of application No. PCT/CN2021/124176, filed on Oct. 15, 2021.

(51) Int. Cl. G06F 30/27

(52) U.S. Cl. CPC G06F 30/27

(57) ABSTRACT

A method for predicting performance of LED structure is provided. The prediction method mainly includes: collecting and extracting input feature parameters and output feature parameters of LED structures, and constructing corresponding datasets; preprocessing data in the datasets; constructing a model using a machine learning algorithm, setting structural parameters of the model, and performing initialization training on the model to obtain an initial model; using preprocessed datasets to train and optimize the initial model, thereby obtaining a prediction model; inputting input feature parameters of an LED structure to be predicted into the prediction model, thereby obtaining prediction values of output feature parameters of the LED structure to be predicted. The prediction method can predict the performance of LED structure, has short prediction time, and has high prediction accuracy.

### TECHNICAL FIELD

The disclosure relates to the technical field of semiconductor electronic devices, and particularly to a method for predicting the performance of light-emitting diode (LED) structure using a machine learning algorithm model.

### BACKGROUND

LEDs have the characteristics of high efficiency, energy saving, environmental protection, and long service life, and have been widely used in many fields, such as traffic indication, architectural decoration, and display lighting. Specifically, semiconductor materials such as indium gallium nitride (InGaN) and gallium nitride (GaN) are developed and commercialized rapidly.

Since the establishment of the topic “Research on GaN-based materials and blue-green light devices” in China in 1994, InGaN-based LEDs and GaN-based LEDs have been widely used in fields such as general lighting, liquid crystal display (LCD) backlighting, outdoor displays, landscape lighting, and automotive lighting. GaN-based LED products are leading in the field of solid-state lighting and are energy-efficient alternatives to incandescent and fluorescent lamps.

A structural design of high-performance LED usually uses a trial-and-error method to confirm the quality of performance optimization results of LED by referring to previous simulations or experimental results. In the fields of synthesis and development of materials, designs for new structures, and new manufacturing technologies, the performance optimization of devices generally takes a long time and consumes a large amount of resources, such as time, materials, equipment, and manpower.

Machine learning is an interdisciplinary discipline that covers knowledge of probability theory, statistics, approximate theory, and complex algorithms. Machine learning uses computers as tools and aims to simulate human learning methods in real-time, and divides existing contents into knowledge structures to effectively improve learning efficiency. Machine learning is the science of studying how to use computers to simulate or implement human learning activities, and machine learning is one of the most intelligent and cutting-edge research fields in artificial intelligence. Machine learning is a common research hotspot in the fields of artificial intelligence and pattern recognition, and its theories and methods have been widely applied to solve complex problems in engineering applications and scientific fields. Based on the rapid development of internet technology, when a machine learning method in artificial intelligence is applied to the structural design of LED, the efficiency of improving the structure of LED may be greatly increased.

In the structural design of high-performance LED, how to use the machine learning method to predict the performance of a designed LED structure, and adjust the structural design scheme of the LED timely based on the predicted results to obtain more efficient electronic devices has become one of the problems that those skilled in the art need to solve.

### SUMMARY

To solve the shortcomings of the performance prediction in the structural design of high-performance LED structure in the related art, the disclosure provides a method for predicting performance of LED structure (also referred to as structural performance of LED). The method can use different algorithmic models (such as neural network model, decision tree, and multilayer perceptron (MLP)) of machine learning to predict the performance of high-performance LED structure, and the method can adjust the design scheme of LED structure timely based on a prediction result, thereby making the design of high-performance LED structure achieve better luminous performance in the whole.

In an embodiment, a method for predicting performance of LED structure includes:
step S1, collecting and extracting data including input feature parameters of LED structures and output feature parameters corresponding to the input feature parameters, and dividing the data into an original dataset and a testing dataset;
step S2, preprocessing the original dataset and the testing dataset to obtain a preprocessed dataset and a preprocessed testing dataset;
step S3, constructing an initial model by using a machine learning algorithm;
step S4, setting structural parameters of the initial model, and performing initialization training on the structural parameters to obtain an initialized model;
step S5, optimizing the initialized model: using the preprocessed dataset to train the initialized model to obtain network weights and biases, thereby obtaining a prediction model; and
step S6, inputting input feature parameters of an LED structure to be predicted into the prediction model, thereby obtaining prediction values of output feature parameters of the LED structure to be predicted.

Specifically, in the step S1, since the LED structures are complex, the numbers of input feature parameters and output feature parameters corresponding to the input feature parameters are adjusted according to actual needs, thereby reducing computational complexity. The LED structures are divided into original LED structures and LED structures to be tested. The original dataset is constructed based on input feature parameters of the original LED structures and output feature parameters of the original LED structures. The testing dataset is constructed based on input feature parameters of the LED structures to be tested and output feature parameters of the LED structures to be tested.

In an embodiment, the input feature parameters of the LED structures include structures of barrier layers of multiple quantum well (MQW) regions of the LED structures, compositions of the barrier layers of the MQW regions of the LED structures, thickness of the barrier layers of the MQW regions of the LED structures, structures of potential well layers of the MQW regions of the LED structures, compositions of the potential well layers of the MQW regions of the LED structures, thickness of the potential well layers of the MQW regions of the LED structures, structures of electron blocking layers of the LED structures, compositions of the electron blocking layers of the LED structures, and contents of the electron blocking layers of the LED structures; the output feature parameters corresponding to the input feature parameters comprise internal quantum efficiency of the LED structures, optical output power of the LED structures, current densities corresponding to the optical output powers of the LED structures, IQE, IQE droop, peak current densities, etc.

In an embodiment, the machine learning algorithm includes at least one selected from the group consisting of a deep learning algorithm, a multilayer perceptron algorithm, a decision tree algorithm, a linear regression algorithm, and a gradient boosting regression algorithm. Moreover, the deep learning algorithm includes at least one selected from the group consisting of a convolutional neural network (CNN) algorithm, a recurrent neural network (RNN) algorithm, an auto encoder algorithm, and a deep belief network (DBN) algorithm.

In an embodiment, in the method for predicting performance of LED structure, each of the LED structures is one type selected from the group consisting of an InGaN-based visible light LED, a AlGaN-based deep ultraviolet LED, a GaAs-based LED, a GaAlAs-based LED, and a GaP-based LED. Moreover, the LED structure are LED structures which include PN junctions and quantum well layers.

Since LED structures are more complex compared to other optoelectronic devices, the selection of structural feature parameters should be based on the importance of structural features and actual needs. Therefore, the input feature parameters of the LED structure and the output feature parameters corresponding to the input feature parameters are screened and adjusted based on types of the LED structures. In other words, the input feature parameters of the LED structure and the output feature parameters corresponding to the input feature parameters can be reduced or expanded according to actual needs.

In an embodiment, the preprocessing the original dataset and the testing dataset includes:
selecting features: selecting the input feature parameters of the LED structures based on known physical knowledge and relationships among the data, thereby obtaining selected feature parameters;
data processing: normalizing the selected feature parameters to obtain processed feature parameters; and
data restructuring: restructuring sizes of the processed feature parameters to obtain the preprocessed dataset and the preprocessed testing dataset.

In an embodiment, a mean value of the processed feature parameters is 0 and a standard deviation of the processed feature parameters is 1 after the selected feature parameters are normalized.

In an embodiment, after the initialized model is trained, a mean square error formula is configured to determine a training result of the initialized model, and the mean square error formula is expressed as:

$$M S E = \frac{{\sum }_{i = 1}^{N} {( {Predict}_{i} - {Actual}_{i} )}^{2}}{N} ;$$

in the mean square error formula, Predictᵢ represents a prediction value of an i-th sample, Actualᵢ represents an actual value of the i-th sample, and N represents the total number of samples.

In an embodiment, a neural network model in the deep learning algorithm is a convolutional neural network model. The convolutional neural network model includes an input layer, multiple convolutional layers, multiple fully connected layers, and an output layer. The input layer is configured to input the input feature parameters of the LED structures. The multiple convolutional layers are connected to the input layer and configured for performing feature extraction on the input feature parameters inputted by the input layer. After the feature extraction, data of the multiple convolutional layers are processed and connected to the multiple fully connected layers, and neurons are set in the multiple fully connected layers for prediction. The output layer is connected to the multiple fully connected layers, and the output layer is configured to output prediction values of the output feature parameters of the LED structures.

In an embodiment, steps for setting structural parameters of the convolutional neural network model and performing initialization training on the structural parameters are as follows: the convolutional neural network model sequentially includes a first convolutional layer, a second convolutional layer, a first fully connected layer, and a second fully connected layer; the first convolutional layers and second convolutional layers have the same configuration and different total numbers of cores; the first fully connected layer adopts a dropout strategy to reduce overfitting; weights in the first convolutional layer and the second convolutional layer are initialized to truncated normal distribution noise (also referred to as noise that follows a truncated normal distribution noise); the bias in the network is initialized to a constant; a learning rate is set within a numerical range based on features of training samples, thereby determining a batch size of the training samples; the convolutional neural network model is trained repeatedly based on the setting of the training samples, and the total number of training rounds is determined, thereby optimizing the convolutional neural network model.

In an embodiment, the weights in the first convolutional layer and the second convolutional layer are initialized as noise that follows a truncated normal distribution with a mean value of 0 and a standard deviation of 0.1. The bias in the network is initialized to a constant of 1. The learning rate is in a range of 0.00001-0.1. The total number of the training rounds is in a range of 100-500.

In an embodiment, a design scheme of the LED structure to be predicted is adjusted based on the prediction values of output feature parameters of the LED structure to be predicted.

Based on the above technical solutions, compared with existing simulation software such as APSYS, the method for predicting the performance of LED structure provided by the disclosure has the following effects:

1. Since different algorithm models in machine learning are used to predict the performance of LED structure, the prediction method of the disclosure can quickly predict the structural performance of different LED devices without considering whether the network structure fitting has converged in the model, and it is better to optimize structural design schemes of high-performance LED based on the prediction.

2. The neural network model used in the machine learning algorithm of the disclosure can effectively prevent or reduce the overfitting of the neural network model by using a dropout strategy and other strategies, thereby improving the accuracy of the neural network model in predicting the performance of high-performance LED structures.

3. In the disclosure, big data is processed by machine learning to construct the neural network model, and the performance of different high-performance LED structures is predicted by using the neural network model. Therefore, hidden rules of LED performance changing with structure can be found from these data, without using physical mechanism analysis to obtain the hidden rules. From this, the disclosure can explore more complex physical rules in the overall structure of high-performance LEDs based on these data, which is easy to implement.

The other features and beneficial effects of the disclosure will be described clearer in subsequent contents, and will be understood through embodiments of the disclosure. The purpose and other beneficial effects of the disclosure can be achieved through the structures specifically pointed out in the specification, claims, and attached drawings.

### BRIEF DESCRIPTION OF DRAWINGS

In order to provide a clearer explanation of the embodiments of the disclosure or the technical solutions in the related art, a brief introduction will be given to the attached drawings required in the description of the embodiments or related art. It is apparent that the attached drawings in the following description are some embodiments of the disclosure. Those of ordinary skill in the art may obtain other drawings based on the attached drawings without creative work. The positional relationships described in the attached drawings in the following description, unless otherwise specified, are based on the direction indicated by the components in the attached drawings.

FIG. 1 illustrates a structural schematic diagram of an LED in an embodiment of the disclosure.

FIG. 2 illustrates a schematic diagram of a classic neural network model in the disclosure.

FIG. 3 illustrates a flowchart of the method for predicting the performance of LED structure in an embodiment of the disclosure.

FIG. 4 illustrates a structural schematic diagram of a convolutional neural network configured to predict the performance of LED structure.

FIG. 5 illustrates a structural schematic diagram of a convolutional neural network model in an embodiment of the disclosure.

FIG. 6 illustrates a comparison diagram between IQE predicted by the convolutional neural network model of the disclosure and IQE of APSYS simulation.

FIG. 7 illustrates a comparison diagram between the IQE predicted by a multilayer perceptron model of the disclosure and the IQE of APSYS simulation.

FIG. 8 illustrates a local structural schematic diagram of the decision tree configured to predict the performance of the LED structure in the disclosure.

### DESCRIPTION OF REFERENCE NUMERALS

10—substrate; 11—undoped GaN layer; 12—n-type layer; 13—multi-quantum well layer; 14—electron blocking layer; 15—p-type layer; 16—p-contact; 17—n-contact.

### DETAILED DESCRIPTION OF EMBODIMENTS

In order to make the purposes, technical solutions, and advantages of the embodiments of the disclosure clearer, the following will provide a clear and complete description of the technical solutions in the embodiments of the disclosure in conjunction with the attached drawings. Apparently, the described embodiments are a part of the embodiments of the disclosure, not all of them. The technical features designed in different embodiments of the disclosure described below can be combined with each other as long as they do not conflict with each other. Based on the embodiments of the disclosure, all other embodiments obtained by those of ordinary skill in the art without creative work should fall within the scope of protection of the disclosure.

In the description of the disclosure, it should be noted that all terms used (including technical and scientific terms) have the same meanings as those commonly understood by those skilled in the art, and cannot be understood as a limitation to the disclosure. It should be further understood that the terms used in the disclosure should be understood to have meanings consistent with their meanings in the context and related art of the specification, and should not be understood in idealized or overly formal meanings unless the terms are clearly defined in the disclosure.

In structural designs of high-performance LEDs, GaN-based LEDs have developed for nearly thirty years, and thus the GaN-based LEDs have sufficient theoretical and data support. For the convenience of explanation and understanding, a structure of GaN-based LED is taken as an example in the description of embodiments of the disclosure, and different algorithm models in machine learning are used to explain the method for predicting the performance of LED structure. The method for predicting the performance of LED structure of the disclosure is not limited to the GaN-based LED. The method for predicting the performance of LED structure provided by the disclosure can also be applied to the performance prediction of different LED structures such as InGaN-based visible light LED, AlGaN-based deep ultraviolet LED, GaAs-based LED, GaAlAs-based LED, and GaP-based LED. It should be further explained that the LED structure as an example described in the disclosure an LED structure including a PN junction and a quantum well layer.

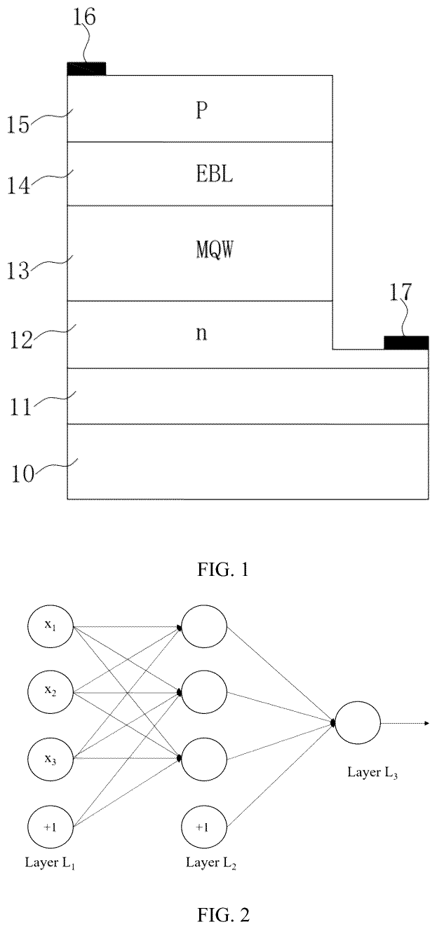

Referring to FIG. 1, FIG. 1 illustrates a structural schematic diagram of an LED in an embodiment of the disclosure. As shown in FIG. 1, the LED structure is a GaN-based LED. The GaN-based LED is an LED which includes a PN junction. The overall structure of the GaN-based LED mainly includes a substrate 10, and an undoped GaN layer 11, an n-type layer 12, a multi-quantum well layer 13, an electron blocking layer 14, a p-type layer 15, a p-contact 16, and an n-contact 17 stacked sequentially on the substrate 10. As shown in FIG. 1, in the embodiment, the substrate 10 is a sapphire substrate, the n-type layer 12 is an n-type doped GaN layer (n-GaN), and the p-type 15 layer is a p-type doped GaN layer (p-GaN). The multi-quantum well layer 13 includes an InGaN layer and a GaN layer, and the InGaN layer and the GaN layer are grown alternately. In other words, the multi-quantum well layer 13 uses multiple periods of InGaN/GaN multiple quantum wells as composite luminescent regions. The undoped GaN layer is disposed between the substrate 10 and the n-type doped GaN layer, and the undoped GaN layer is configured as a buffer layer. The p-contact is formed at an end of the p-type layer, and the n-contact is formed at an end of the n-type layer.

Referring to FIG. 1, in the embodiment, the GaN-based LED is a GaN-based blue light LED and adopts an InGaN/GaN multi-quantum well structure. The GaN-based blue light LED structure can improve the luminous efficiency of a chip, so that the electronic devices made of the GaN-based blue light LED structure have the advantages of high brightness and high luminous efficiency. In the GaN-based blue light LED structure, factors that have a significant impact on the luminous efficiency of electronic devices include but are not limited to the multi-quantum well layer 13 and the electron blocking layer 14. Both the multi-quantum well layer 13 and the electron blocking layer 14 have various structures, and the combination of the multi-quantum well layer 13 and the electron blocking layer 14 is various. In order to improve the luminous efficiency of electronic devices, it is necessary to pay more attention to the structures of the multi-quantum well layer 13 and the electron blocking layer 14 during the design process of the GaN-based blue light LED structure and to make efficient and accurate predictions of the structural performance of the multi-quantum well layer 13 and the electron blocking layer 14.

With the development of machine learning, there are many types of machine learning methods published in research, and the machine learning methods are classified based on different aspects. Based on the classification of learning strategies, machine learning can be divided into machine learning that simulates the human brain and machine learning that directly adopts mathematical methods. The machine learning that simulates the human brain can be further divided into symbol learning and neural network learning (or connection learning). The machine learning that directly adopts mathematical methods mainly includes statistical machine learning. Based on the classification of learning methods, machine learning can be divided into inductive learning, deductive learning, analogical learning, and analytical learning. Inductive learning can be further divided into symbolical inductive learning (such as example learning and decision tree learning) and functional inductive learning (also known as discovery learning, such as neural network learning, example learning, discovery learning, and statistical learning). Based on the classification of learning methods, machine learning can be divided into supervised learning, unsupervised learning, and reinforcement learning. Based on the classification of data forms, machine learning can be divided into structured learning and unstructured learning. Based on the classification of learning objectives, machine learning can be divided into concept learning, rule learning, function learning, category learning, and Bayesian network learning.

The commonly used algorithms in machine learning include but are not limited to the decision tree algorithm, the naive Bayesian algorithm, the support vector machine algorithm, the random forest algorithm, the artificial neural network algorithm, the boosting algorithm, the bagging algorithm, the association rule algorithm, the EM (expectation maximization) algorithm, and the deep learning (DL) algorithm. Specifically, as a new research direction in the field of machine learning (ML), deep learning can learn the inherent rules and representation levels of sample data. The ultimate goal of deep learning is to enable machines to have the ability to analyze and learn like humans, and to recognize data such as texts, images, and sounds.

Different deep learning models are mainly constructed based on neural networks. A neural network is an algorithmic mathematical model that mimics the behavioral characteristics of biological neural networks. It can generate an output after receiving multiple inputs. With the continuous development of neural networks and the iterative updating of deep learning algorithms, the structure of network models is also constantly adjusted and optimized, especially in the areas of feature extraction and feature selection, which will have greater room for improvement. The neural networks can map any complex nonlinear relationship and has strong robustness, memory ability, self-learning ability, etc. The neural networks are widely used in classification, prediction, pattern recognition, etc.

Based on the above content, in the embodiment of the disclosure, the machine learning algorithm includes at least one selected from the group consisting of a deep learning algorithm, a multilayer perceptron algorithm, a decision tree algorithm, a linear regression algorithm, and a gradient boosting regression algorithm. Specifically, the deep learning algorithm includes one selected from the group consisting of a convolutional neural network algorithm, a recurrent neural network algorithm, an auto encoder algorithm, and a deep belief network algorithm.

Referring to FIG. 2, FIG. 2 illustrates a schematic diagram of a classic neural network model in the disclosure. The neural network is an algorithmic mathematical model that simulates human neural networks to process information. The neural network is a complex network system formed by a large number of simple processing units (also referred to as neurons) widely interconnected, and it is a highly complex nonlinear dynamic learning system. A neuron is a multi-input and single output information processing unit that processes information nonlinearly. The neural network is one of models in machine learning.

Similar to the actual human neural network, the neural network includes neurons and connections (synapses) between nodes. Each neural network unit is known as a perceptron configured to receive multiple input information and produce output information. Usually, the actual neural network decision model is a multi-layer network including multiple perceptrons. Referring to FIG. 2, a classic neural network model mainly includes an input layer, a hidden layer, and an output layer. As shown in FIG. 2, LayerL₁ represents the input layer, LayerL₂ represents the hidden layer, and LayerL₃ represents the output layer. Based on the advantages of the neural network model in machine learning, in the process of designing the GaN-based blue light LED structure shown in FIG. 1, the neural network model can be used to efficiently and accurately predict feature factors that affect the luminous efficiency of electronic devices. Based on a prediction result, the design scheme of the GaN-based blue light LED structure can be adjusted in time to meet expectant effects. The feature factors mentioned include, but are not limited to, the structural performance of the multi-quantum well layer (i.e., MQW in FIG. 1) 13 and the electron blocking layer (i.e., EBL in FIG. 1) 14.

Referring to FIG. 2, in a feedforward neural network, information moves forward in only one direction, that is, the information moves from input nodes to output nodes through hidden nodes. There are no loops or loops in the network in FIG. 2. In the field of machine learning, typical deep learning models can mainly include three types: (1) a convolutional neural network system based on convolutional operations; (2) a self-coding neural network based on multilayer neurons, including auto encoder and sparse coding; and (3) a deep belief network (DBN) which is pre-trained in a manner of the multi-layer self-coding neural network and combines with discriminative information to optimize neural network weights.

In addition to the three typical deep learning models mentioned above, deep learning models can also be recurrent neural networks, recursive neural networks, etc.

The convolutional neural network is a deep feedforward network with local connectivity, weight sharing, and other features. The convolutional neural network consists of three parts: a first part is an input layer; a second part includes a combination of multiple convolutional layers and pooling layers (also referred to as hidden layers); a third part includes a fully connected multilayer perceptron classifier (also referred to as a fully connected layer). The convolutional neural network includes a feature extractor composed of convolutional layers and subsampling layers. In convolutional layers of the convolutional neural network, a neuron is only connected to some of neurons of adjacent layers. A convolutional layer of the convolutional neural network usually includes several feature maps, each feature map is composed of neurons arranged in a rectangular shape. Neurons in the same feature map share weights, and the shared weights are called convolutional kernels. Convolutional kernels are usually initialized in the form of a random decimal matrix, and the convolutional kernels will obtain reasonable weights by learning during the training process of the network. The direct benefit of sharing weights (convolutional kernels) is to reduce connections between layers of the network, while also reducing the risk of overfitting. Subsampling, also known as pooling, typically includes two forms: mean subsampling (mean pooling) and maximum subsampling (max pooling). Subsampling layer, also known as pooling layer, is configured for feature selection, thereby reducing the number of features and parameters. Subsampling can be seen as a special convolutional process. Convolutional kernels and subsampling greatly simplify model complexity and reduce model parameters.

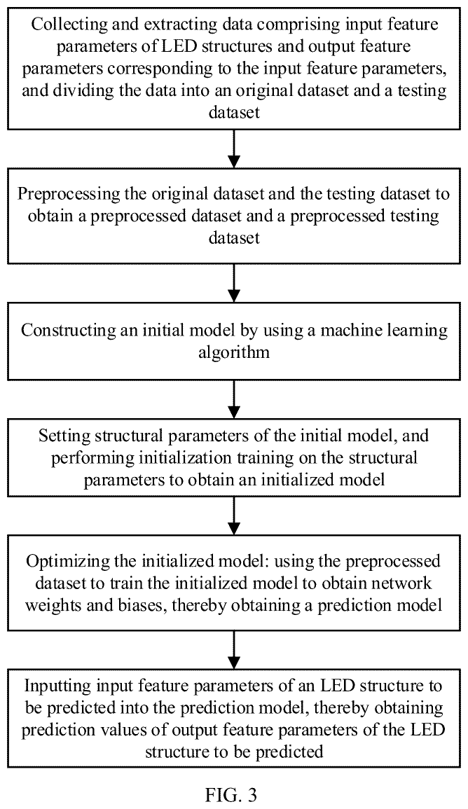

Referring to FIG. 1 and FIG. 3, FIG. 3 illustrates a flowchart of the method for predicting the performance of LED structure in an embodiment of the disclosure. Taking the GaN-based LED structure (i.e., the GaN-based blue light LED having a multi-quantum well structure) shown in FIG. 1 as an example, a method for predicting the performance of LED structure using a machine learning algorithm model includes:
step S01: collecting and extracting data including input feature parameters of a large number of GaN-based LED structures and corresponding output feature parameters, and dividing the data into an original dataset and a testing dataset; and preprocessing the original dataset and the testing dataset to obtain a preprocessed dataset and a preprocessed testing dataset;
step S02: constructing an initial model using a machine learning algorithm;
step S03: setting structural parameters of the initial model, and performing initialization training on the structural parameters to obtain an initialized model;
step S04: using the preprocessed dataset to train and optimize the initialized mode, thereby obtaining a prediction model; and
step S05: inputting input feature parameters of the preprocessed testing dataset into the prediction model, thereby obtaining prediction values of output feature parameters of GaN-based LED structures to be tested; then evaluating a training result of the prediction model based on the prediction values of the GaN-based LEDs to be tested;
step S06: when the training result of the prediction model is satisfied, inputting input feature parameters of a GaN-based LED structure to be predicted into the prediction model, thereby obtaining prediction values of output feature parameters of the LED structure to be predicted.

After obtaining the prediction values of the output feature parameters of the LED structure to be predicted, a design scheme of the GaN-based LED structure to be predicted can be adjusted based on the prediction values of the output feature parameters of the LED structure to be predicted.

In the step S01, the GaN-based LED structures include original GaN-based LED structures and GaN-based LED structures. Input feature parameters and output feature parameters of the original GaN-based LED structures are used to construct the original dataset. Input feature parameters and output feature parameters of the GaN-based LED structures to be tested are used to construct the testing dataset. Furthermore, the original dataset is processed to obtain the preprocessed dataset, and the testing dataset is processed to obtain the preprocessed testing dataset.

In the step S04, the training result of the prediction model is evaluated by a mean square error formula. The mean square error formula is expressed as:

$$M S E = \frac{{\sum }_{i = 1}^{N} {( {Predict}_{i} - {Actual}_{i} )}^{2}}{N} ,$$

where Predictᵢ represents a prediction value of an i-th sample, Actualᵢ represents an actual value of the i-th sample, and N represents the total number of samples. Specifically, Predictᵢ represents a prediction value of output feature parameters of i-th GaN-based LED structure to be tested. Actualᵢ represents an actual value of the output feature parameters of the i-th GaN-based LED structure to be tested.

In addition, when the training result of the prediction model is not satisfied for prediction, structural parameters of the prediction model is adjusted, then the preprocessed dataset is used to train and optimize the prediction model again until the training result is satisfied. The prediction model is optimized in a training process according to a mean square error formula expressed as:

$$M S E = \frac{{\sum }_{i = 1}^{N} {( {Predict}_{i} - {Actual}_{i} )}^{2}}{N} .$$

Correspondingly, Predictᵢ represents a prediction value of output feature parameters of i-th original GaN-based LED structure. Actualᵢ represents an actual value of the output feature parameters of the i-th original GaN-based LED structure.

In an embodiment, the training and prediction process of the prediction model includes:
step S11: selecting feature parameters from the original dataset as input data for the model;
step S12: preprocessing the original dataset and normalizing data;
step S13: extracting sample data from the preprocessed dataset and performing multi-batch division on the sample data; and
step S14: performing multiple rounds of training on the preprocessed dataset after the multi-batch division, and outputting prediction values of the output feature parameters.

In an embodiment, when the prediction model is set, the parameters of the prediction model include but are not limited to the number of convolutional kernels, lengths of convolutional kernels, and activation functions.

Specifically, the following will explain how to use different machine learning models to predict the performance of the GaN-based LED structure.

Embodiment 1: a deep learning algorithm model in machine learning is used to predict the performance of LED structure.

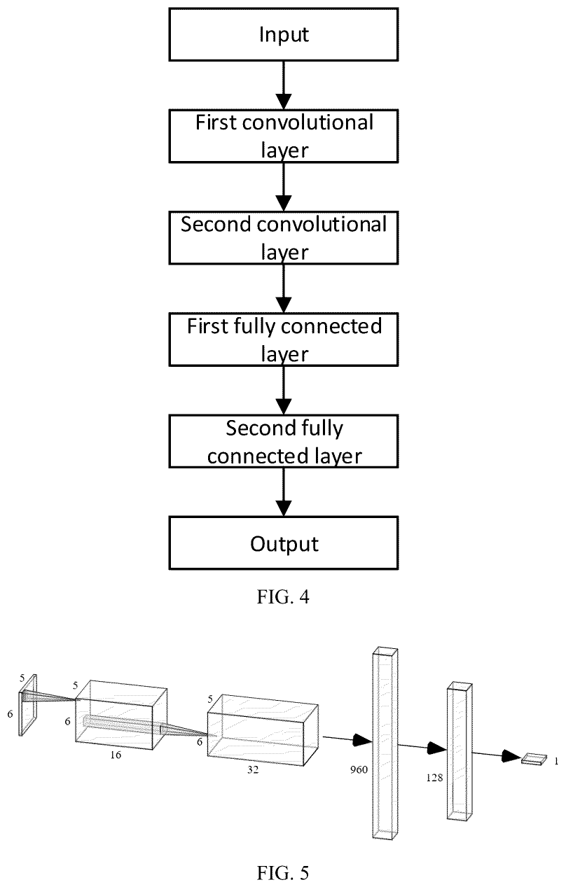

Referring to FIG. 1 to FIG. 5, FIG. 4 illustrates a structural schematic diagram of a convolutional neural network configured to predict the performance of LED structure. FIG. 5 illustrates a structural schematic diagram of a convolutional neural network model in an embodiment of the disclosure. In FIG. 5, a neural network model constructed by convolutional neural networks is taken as an example for explanation. A method for predicting the performance of the multi-quantum well structure of the GaN-based LED using a convolutional neural network algorithm model includes the following steps S1 to S6.

Step S1: data including input feature parameters of multi-quantum well structures of the GaN-based LEDs and corresponding output feature parameters is collected and extracted, and the input feature parameters and the output feature parameters are used to construct corresponding datasets.

In processes of collecting and extracting data including input feature parameters of multi-quantum well structures of the GaN-based LEDs, the data of the multi-quantum well structures of the GaN-based LEDs need to be selected. In processes of selecting the data, data collection and data extraction are performed on the data to obtain the input feature parameters which have main influences on prediction values of the output feature parameters of the multi-quantum well structures of GaN-based LEDs. The input feature parameters of the multi-quantum well structure of the GaN-based LED include structures of barrier layers of quantum well regions, compositions of the barrier layers of the quantum well regions, contents of the barrier layers of the quantum well regions, structures of potential well layers of the quantum well regions, compositions of the potential well layers of the quantum well regions, contents of the potential well layers of the quantum well regions, structures of electron blocking layers, compositions of the electron blocking layers, and contents of the electron blocking layers. The prediction values of the output feature parameters of a GaN-based LED structure include IQE of the LED structure, optical output power of the LED structure, a current density corresponding to the optical output power of the LED structure, IQE, IQE droop, peak current density, etc.

Then, the input feature parameters and the output feature parameters are used to construct an original dataset and a testing dataset. The original dataset and the testing dataset need to be preprocessed. The parameters of the original dataset and the testing dataset can represent the quantum well region or the electron blocking layer, which uses complex structures such as super-lattice structures or gradient structures, and therefore, a large amount of data of the LED structures can be collected and recorded. Therefore, data of each LED structure can be taken as a sample, and data of multiple LED structures can be taken as a sample set. Each sample or each sample set can be taken as an input layer in the neural network.

Step S2: the input feature parameters and the output feature parameters of the datasets (i.e., the original dataset and the testing dataset) in step S1 are preprocessed to obtain a preprocessed dataset and a preprocessed testing dataset. A method of preprocessing the datasets includes:
(1) in the datasets, selecting and sorting input feature parameters of the LED structures based on known physical knowledge, relationships among various data, and influences on the physical quantities (for example, IQE) to be predicted, thereby obtaining selected input feature parameters;
(2) normalizing the selected input feature parameters to obtain normalized feature parameters based on an normalization formula; the normalization formula being expressed as:

$${x}^{′} = \frac{x - μ}{σ} ,$$

where x represents the selected input feature parameters and x′ represents the normalized feature parameters, u represents a mean value of samples, and σ represents a standard deviation of the samples; after the normalization, the selected input feature parameters follow a standard normal distribution, and the selected input feature parameters have a mean value of 0 and a standard deviation of 1 on each dimension after the normalization; and
(3) restructuring sizes of normalized data and performing multi-batch division on the normalized data.

Furthermore, since an input dimension required in a two-dimensional convolutional neural network includes four dimensions (batchsize, height, width, depth), the original data of the embodiment is an array in a txt file. Therefore, the arrangement of the original data needs to be adjusted to match an input size of the two-dimensional convolutional neural network.

Step 3: a convolutional neural network model is constructed based on a deep learning algorithm in machine learning.

Referring to FIG. 4, the convolutional neural network model constructed by the convolutional neural network mainly includes an input layer, multiple convolutional layers, multiple fully connected layers, and an output layer in sequence. The layers are connected to each other in sequence. The input layer can be used to input data or datasets of input feature parameters of samples or sample sets of the LED structures, such as the preprocessed dataset and the preprocessed testing dataset.

As shown in FIG. 4, in the structure of the convolutional neural network model, there are two convolutional layers after the input layer, and each convolutional layer contains an activation function.

Each of the convolutional layers extracts a feature map by performing a convolutional calculation on the convolutional kernel and the feature map. A convolutional process of the first convolutional kernel is expressed as: x^{(l)}=Σx^{(l-1)}*ω^{(l)}+b^{(l)}, where x represents the element in feature map, * represents a convolutional calculation, ω^{(l)} represents neuron weights of l-th layer, and b^{(l)} represents a bias of l-th layer. Ordinarily, a size of an input matrix is expressed as w, a size of a convolutional kernel is expressed as k, a step size is expressed as s, the number of zero padding layers is expressed as p, and a formula for calculating the size of the feature map after the convolution process is expressed as:

$${ω}^{′} = \frac{ω + 2 p - k}{s} + 1.$$

In the embodiment, zero padding is performed on the feature map to maintain the size of the feature map after the convolution process.

The activation function in each of the convolutional layers is a rectified linear unit (Relu). A formula of the rectified linear unit is expressed as: f(x)=max(0,x), where x represents the element in feature map, which can complete nonlinear transformation of the feature map.

The second convolutional layer performs feature extraction on the feature map obtained after processing of the activation function, and the feature map activated by the linear rectification function in the second convolutional layer is transmitted to the next part, such as the fully connected layer.

Referring to FIG. 4 and FIG. 5, the convolutional neural network model in FIG. 5 has two fully connected layers. The feature map obtained by the convolutional layers is flattened and then connected to the first fully connected layer which has 128 neurons. Considering that the number of the training samples used in the embodiment is small, a dropout strategy is adopted to suppress or reduce overfitting, and 20% of neurons randomly inactivated in each training round. For the feature map that have been processed by activation functions, the final prediction is completed using the second fully connected layer.

Step S4: network structure parameters of the constructed convolutional neural network model are set, and initialization training is performed on the network structure parameters to obtain an initialized convolutional neural network model.

A method of performing the initialization training on the network structure parameters of is as follows: a step size of the first convolutional layer is set to 1, the number of output channels is 16, and a padding mode is set to same. A step size of the second convolutional layer is set to 1, the number of output channels is 32, and a padding mode is set to same. Weights in the first convolutional layer and the second convolutional layer are initialized to truncated normal distribution noise with a mean value of 0 and a standard deviation of 0.1. All biases in the network are initialized to a constant of 1. A learning rate is set within a numerical range based on features of the training samples to determine a batch size of the training samples. The convolutional neural network model is trained repeatedly based on the setting of the training samples, and the total number of training rounds is determined, thereby completing the initialization training of the convolutional neural network model. Specifically, the learning rate is set in a range of 0.00001-0.1, and the total number of training rounds is in a range of 100-500.

Specifically, the learning rate is set to 0.0001. As shown in FIG. 5, the batch size of the training samples is set to 16, that is, 16 images are transmitted into the convolutional neural network in each training round, then the average loss of all samples in each training round. The total number of the training rounds is 300, a stochastic gradient descent (SGD) algorithm is used to perform preliminary optimization on the convolutional neural network model.

Step S5: the preprocessed dataset in step S2 is used to train and optimize the initialized convolutional neural network model to obtain and save network weights and biases of the convolutional neural network model, thereby obtaining a convolutional neural network prediction model; and input feature parameters of the preprocessed testing dataset are inputted into the convolutional neural network prediction model to obtain prediction values of output feature parameters of the preprocessed testing dataset, thereby evaluating a training result of the convolutional neural network prediction model based on actual values and prediction values of output feature parameters of the preprocessed testing dataset.

In machine learning, a loss function is used to measure a loss or a difference between prediction values outputted by the model and target values (i.e., actual values). Therefore, in step S5, the loss function used in the training of the convolutional neural network model is expressed by using a mean square error formula, thereby evaluating the quality of the training result of the convolutional

$$M S E = \frac{{\sum }_{i = 1}^{N} {( {Predict}_{i} - {Actual}_{i} )}^{2}}{N} ,$$

where Predictᵢ represents a prediction value of the i-th sample, Actualᵢ represents an actual value of the i-th sample, and N represents the total number of samples. The closer the value of MSE is to 0, the better the training and the optimization result of the convolutional neural network model is, and the higher the accuracy of output result is. Therefore, when the convolutional neural network prediction model obtained after training and optimization is used to predict the performance of LED structure, the accuracy of the prediction values is higher.

Step S6: input feature parameters of a GaN-based LED structure to be predicted are inputted into the convolutional neural network prediction model, thereby obtaining prediction values of output feature parameters of the GaN-based LED structure to be predicted. The prediction values of the output feature parameters of the LED structure include but are not limited to IQE of the GaN-based LED structure to be predicted, optical output power of the GaN-based LED structure to be predicted, and a current density corresponding to the optical output power.

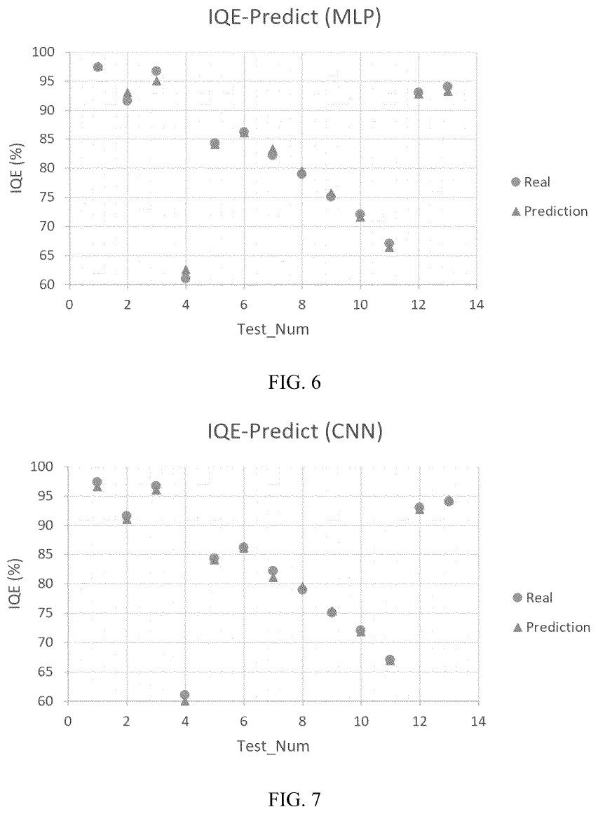

A Python compilation platform can be used to train and predict the convolutional neural network prediction model, and FIG. 6 illustrates a comparison diagram between IQE predicted by the convolutional neural network model of the disclosure and IQE of APSYS simulation. In FIG. 6, the predicted IQE value is basically consistent with the actual value, a loss percentage is 0.2422%, which means the predicted IQE value (also referred to as IQE of the GaN-based LED structure) is kept within a small error range.

Embodiment 2: a multilayer perceptron model in machine learning is used to predict the performance of LED structure.

Multilayer perceptron is a feedforward artificial neural network model that maps multiple input datasets to a single output dataset.

Referring to FIG. 2, FIG. 2 can be a local structural schematic diagram of the multilayer perceptron configured to predict the performance of LED structure in the disclosure. Actually, the multilayer perceptron shown in FIG. 2 includes 30 neurons and 10 hidden layers. A method for predicting performance of the multi-quantum well structure of the GaN-based LED using a multilayer perceptron model includes the following steps M1-M6:

Step M1: data including input feature parameters of multi-quantum well structures of the GaN-based LEDs and corresponding output feature parameters is collected and extracted, and the input feature parameters and the output feature parameters are used to construct corresponding datasets.

In processes of collecting and extracting data including input feature parameters of multi-quantum well structures of the GaN-based LEDs, the data of the multi-quantum well structures of the GaN-based LEDs need to be selected. In processes of selecting the data, data collection and data extraction are performed on the data to obtain the input feature parameters which have main influences on prediction values of the output feature parameters of the multi-quantum well structures of GaN-based LEDs. The input feature parameters of the multi-quantum well structure of the GaN-based LED include structures of barrier layers of quantum well regions, compositions of the barrier layers of the quantum well regions, contents of the barrier layers of the quantum well regions, structures of potential well layers of the quantum well regions, compositions of the potential well layers of the quantum well regions, contents of the potential well layers of the quantum well regions, structures of electron blocking layers, compositions of the electron blocking layers, and contents of the electron blocking layers. The prediction values of the output feature parameters of a GaN-based LED structure include IQE of the LED structure, optical output power of the LED structure, a current density corresponding to the optical output power of the LED structure, IQE, IQE droop, peak current density, etc.

Then, the input feature parameters and the output feature parameters are used to construct an original dataset and a testing dataset. The original dataset and the testing dataset need to be preprocessed. The parameters of the original dataset and the testing dataset can represent the quantum well region or the electron blocking layer, which uses complex structures such as super-lattice structures or gradient structures, and therefore, a large amount of data of the LED structures can be collected and recorded. Therefore, data of each LED structure can be taken as a sample, and data of multiple LED structures can be taken as a sample set. Each sample or each sample set can be taken as an input layer in the neural network.

Step M2: the input feature parameters and the output feature parameters of the datasets (i.e., the original dataset and the testing dataset) in step M1 are preprocessed to obtain a preprocessed dataset and a preprocessed testing dataset. A method of preprocessing the datasets includes:
(1) in the datasets, selecting and sorting input feature parameters of the LED structures based on known physical knowledge, relationships among various data, and influences on the physical quantities to be predicted, thereby obtaining selected input feature parameters;
(2) normalizing the selected input feature parameters; a normalization formula being expressed as:

$${x}^{′} = \frac{x - μ}{σ} ,$$

where x represents the selected input feature parameters and x′ represents the normalized feature parameters, u represents a mean value of samples, and σ represents a standard deviation of the samples; after the normalization, the selected input feature parameters follow a standard normal distribution, and the selected input feature parameters have a mean value of 0 and a standard deviation of 1 on each dimension after the normalization; and
(3) restructuring sizes of normalized data and performing multi-batch division.

Furthermore, since the original data of the embodiment is an array in a txt file. Therefore, the arrangement of the original data needs to be adjusted to match the input size of the multilayer perceptron.

Step M3: a multilayer perceptron model is constructed based on a machine learning algorithm.

Referring to FIG. 2, the multilayer perceptron model mainly includes an input layer, multiple hidden layers, and an output layer in sequence. The layers are connected to each other in sequence. The input layer can be used to input data or datasets of input feature parameters of samples or sample sets of the LED structure.

As shown in FIG. 2, in the structure of the multilayer perceptron model, there is a hidden layer after the input layer, and the hidden layer contains an activation function. The activation function is a rectified linear unit. Nodes in the hidden layer is 10, and the nodes are connected to the output layer.

Step M4: network structure parameters of the constructed multilayer perceptron model are set, and initialization training is performed on the network structure parameters to obtain an initialized multilayer perceptron model.

A method of performing the initialization training on the network structure parameters is as follows: weights in the hidden layer are initialized to truncated normal distribution noise with a mean value of 0 and a standard deviation of 0.1. All biases in the network are initialized to a constant of 1. A learning rate is set within a numerical range based on features of the training samples to determine a batch size of the training samples. The multilayer perceptron model is trained repeatedly based on the setting of the training samples, and the total number of training rounds is determined, thereby completing the initialization training of the multilayer perceptron model. Specifically, the learning rate is set in a range of 0.00001-0.1, and the total number of training rounds is in a range of 100-500.

Specifically, in the embodiment, the learning rate is set to 0.0001. The batch size of the training samples is set to 16, that is, 16 images are transmitted into the multilayer perceptron model in each training round, then calculate the average loss of all samples in each training round. The total number of the training rounds is 1000, a (SGD) algorithm is used to perform preliminary optimization on the multilayer perceptron model.

Step M5: the preprocessed dataset in step M2 is used to train and optimize the initialized multilayer perceptron model to obtain and save network weights and biases of the multilayer perceptron model, thereby obtaining a multilayer perceptron prediction model; and input feature parameters of the preprocessed testing dataset are inputted into the multilayer perceptron prediction model to obtain prediction values of output feature parameters of the preprocessed testing dataset, thereby evaluating a training result of the multilayer perceptron prediction model based on actual values and prediction values of output feature parameters of the preprocessed testing dataset.

A forward propagation process of the multilayer perceptron model is expressed as: X^{(l)}=Y^{(l-1)}W^{(l)}+B^{(l)}, where W^{(l)} represents a weight matrix when a (l−1)-th layer is mapped to a l-th layer, and B^{(l)} represents a bias vector of the I-th layer. The activation function is expressed as: Y^{(l)}=max(0, X^{(l)}). The output feature parameters are obtained by the forward propagation process, then a loss function is calculated, and a backpropagation algorithm is used to obtain partial derivatives of each parameter for further optimization.

In machine learning, a loss function is configured to measure a loss or a difference between prediction values of the model and target values. Therefore, in step M5, the loss function used in the training of the initialized multilayer perceptron model is expressed by using a mean square error formula, thereby determining the quality of the training result of the multilayer perceptron model. The mean square error formula is expressed as:

$$M S E = \frac{{\sum }_{i = 1}^{N} {( {Predict}_{i} - {Actual}_{i} )}^{2}}{N} ,$$

where Predictᵢ represents a prediction value of the i-th sample, Actualᵢ represents an actual value of the i-th sample, and N represents the total number of samples. The closer the value of MSE is to 0, the better the training and optimization result of the multilayer perceptron model is, and the higher the accuracy of output result is. Therefore, when the multilayer perceptron prediction model obtained after training and optimization is used to predict the performance of LED structure, the accuracy of the prediction values is higher.

Step M6: input feature parameters of a GaN-based LED structure to be predicted are inputted into the multilayer perceptron prediction model, thereby prediction values of output feature parameters of the GaN-based LED structure to be predicted is obtained. The prediction values of the output feature parameters of the LED structure include but are not limited to IQE of the GaN-based LED structure, optical output power of the GaN-based LED structure, and a current density corresponding to the optical output power.

A Python compilation platform can be used to train and predict the multilayer perceptron model, and FIG. 7 illustrates a comparison diagram between IQE predicted by the multilayer perceptron model of the disclosure and IQE of APSYS simulation. In FIG. 7, the predicted IQE value (also referred to as IQE of the GaN-based LED structure) is basically consistent with the actual value, a loss percentage is 0.7056%, which means the predicted IQE value is kept within a small error range.

Embodiment 3: a decision tree model in machine learning is used to predict the performance of LED structure.

A decision tree is a tree structure in which each internal node represents division of an attribute, each branch represents a classification output, and each leaf node represents a category.

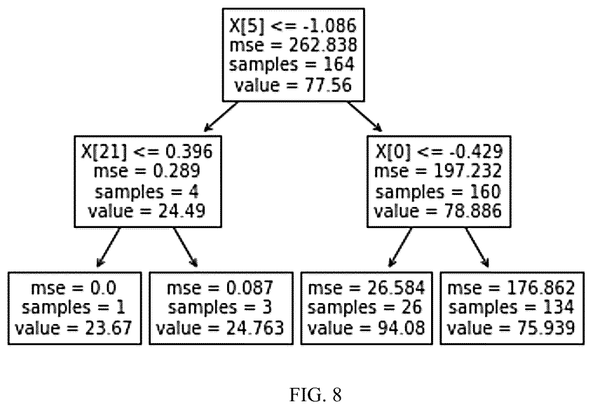

Referring to FIG. 8, FIG. 8 illustrates a local structural schematic diagram of the decision tree configured to predict the structural performance of LED in the disclosure. The decision tree model only has 2 layers shown in FIG. 8, but the decision tree model has 10 layers actually. A method for predicting the performance of the multi-quantum well structure of the GaN-based LED using the decision tree model includes the following steps D1 to D6

Step D1: data including input feature parameters of multi-quantum well structures of the GaN-based LEDs and corresponding output feature parameters is collected and extracted, and the input feature parameters and the output feature parameters are used to construct corresponding datasets.

In processes of collecting and extracting data including input feature parameters of multi-quantum well structures of the GaN-based LEDs, the data of the multi-quantum well structures of the GaN-based LEDs need to be selected. In processes of selecting the data, data collection and data extraction are performed on the data to obtain the input feature parameters which have main influences on prediction values of the output feature parameters of the multi-quantum well structures of GaN-based LEDs. The input feature parameters of the multi-quantum well structure of the GaN-based LED include structures of barrier layers of quantum well regions, compositions of the barrier layers of the quantum well regions, contents of the barrier layers of the quantum well regions, structures of potential well layers of the quantum well regions, compositions of the potential well layers of the quantum well regions, contents of the potential well layers of the quantum well regions, structures of electron blocking layers, compositions of the electron blocking layers, and contents of the electron blocking layers. The prediction values of the output feature parameters of a GaN-based LED structure include IQE of the LED structure, optical output power of the LED structure, a current density corresponding to the optical output power of the LED structure, IQE, IQE droop, peak current density, etc.

Then, the input feature parameters and the output feature parameters are used to construct an original dataset and a testing dataset. The original dataset and the testing dataset need to be preprocessed. The parameters of the original dataset and the testing dataset can represent the quantum well region or the electron blocking layer, which uses complex structures such as super-lattice structures or gradient structures, and therefore, a large amount of data of the LED structures can be collected and recorded. Therefore, data of each LED structure can be taken as a sample, and data of multiple LED structures can be taken as a sample set. Each sample or each sample set can be taken as an input layer in the neural network.

Step D2: the input feature parameters and the output feature parameters of the datasets (i.e., the original dataset and the testing dataset) in step D1 are preprocessed to obtain a preprocessed dataset and a preprocessed testing dataset. A method of preprocessing the datasets includes:
(1) in the datasets, selecting and sorting input feature parameters of the LED structure based on known physical knowledge and relationships among various data, thereby obtaining selected input feature parameters;
(2) normalizing the selected input feature parameters to make the selected input feature parameters have a mean value of 0 and a standard deviation of 1; and
(3) restructuring sizes of normalized data and performing multi-batch division on the normalized data.

Furthermore, since the original data of the embodiment is an array in a txt file. Therefore, the arrangement of the original data needs to be adjusted to match the input size of the decision tree model.

Step D3: a decision tree model is constructed based on a machine learning algorithm.

An impurity function of the decision tree model is expressed as:

$$M S E = \frac{{\sum }_{i = 1}^{N} {( {Predict}_{i} - {Actual}_{i} )}^{2}}{N} ,$$

where Predictᵢ represents a prediction value of the i-th sample, Actualᵢ represents an actual value of the i-th sample, and N represents the total number of samples.

Step D4: pruning the decision tree to reduce overfitting. More specifically, the decision tree is prevented from growing too deep by setting the maximum depth of the decision tree to 10, and the minimum number of samples required to split an internal node of the decision tree is set to 2. This way, the tree is pruned before it is fully grown.

Step D5: the preprocessed dataset in step D2 is used to train and optimize the decision tree model, hyperparameters of the decision tree model are obtained and saved, thereby obtaining a decision tree prediction model; input feature parameters of the preprocessed testing dataset are inputted into the decision tree prediction model to obtain prediction values of output feature parameters of the preprocessed testing dataset, thereby evaluating a training result of the decision tree model based on actual values and prediction values of output feature parameters of the preprocessed testing dataset.

In machine learning, a loss function is configured to measure a loss or a difference between prediction values of the model and target values. Therefore, in step D5, the loss function used in the training of the decision tree model is expressed by using a mean square error formula, thereby determining the quality of the training result of the multilayer perceptron model. The mean square error formula is expressed as:

$$M S E = \frac{{\sum }_{i = 1}^{N} {( {Predict}_{i} - {Actual}_{i} )}^{2}}{N} ,$$

where Predictᵢ represents a prediction value of the i-th sample, Actualᵢ represents an actual value of the i-th sample, and N represents the total number of samples. The closer the value of MSE is to 0, the better the training and optimization result of the decision tree model is, and the higher the accuracy of output result is. Therefore, when the decision tree prediction model obtained after training and optimization is used to predict the performance of LED structure, the accuracy of the prediction values is higher.

Step D6: input feature parameters of a GaN-based LED structure to be predicted are passed down the decision tree prediction model and following the branches until a leaf node is reached. The output value of the leaf node is then used as the prediction of the GaN-based LED structure. Furthermore, the prediction values of the output feature parameters of the GaN-based LED structure include but are not limited to IQE of the GaN-based LED structure, optical output power of the GaN-based LED structure, and a current density corresponding to the optical output power.

Compared with the related art, in a process of designing the multi-quantum well structure of the GaN-based LED, the convolutional neural network prediction model, the multilayer perceptron prediction model, the decision tree prediction model, and other prediction models provided by the disclosure can more accurately predict IQE, optical output power, a current density corresponding to the optical output power, and other luminous efficiency parameters. The prediction result can better guide the optimization of the design scheme for the new GaN-based LED structure, and a new GaN-based LED structure with expected luminous efficiency can be obtained after the optimization. In addition, the convolutional neural network prediction model provided by the disclosure can also predict the predicted values of output parameters of lasers, detectors, etc.

In addition, those skilled in the art should understand that although there are many problems in the related art, each embodiment or technical solution of the disclosure can improve the relate art in only one or several aspects, without simultaneously solving all technical problems mentioned in the related art or background art. Those skilled in the art should understand that the content not mentioned in a claim should not be considered as a limitation to the claim.

Although many terms such as LED, GaN-based LED, machine learning, neural networks, etc. are used in the disclosure, the possibility of using other terms is not ruled out. These terms are only intended to more conveniently describe and explain the essence of the disclosure, and the behaviors of considering these terms as any limitations are contrary to the spirit of the disclosure. The terms “first”, “second”, and the like in the disclosure are used to distinguish similar features and not to describe a specific order or sequence.

Finally, it should be noted that the above embodiments are only used to illustrate the technical solutions of the disclosure and not to limit it. Although the disclosure has been described in detail with reference to the above embodiments, those of ordinary skill in the art should understand that they can still modify the technical solutions mentioned in the above embodiments and equivalently replace some or all of the technical features. These modifications or replacements do not separate the essence of the corresponding technical solutions from the scope of the technical solutions of the embodiments of the disclosure.

What is claimed is:

1. A method for predicting performance of light-emitting diode (LED) structure, comprising:
collecting and extracting data comprising input feature parameters of LED structures and output feature parameters corresponding to the input feature parameters, and dividing the data into an original dataset and a testing dataset;
preprocessing the original dataset and the testing dataset to obtain a preprocessed dataset and a preprocessed testing dataset;
constructing an initial model by using a machine learning algorithm;
setting structural parameters of the initial model, and performing initialization training on the structural parameters to obtain an initialized model;
optimizing the initialized model: using the preprocessed dataset to train the initialized model to obtain network weights and biases, thereby obtaining a prediction model; and
inputting input feature parameters of an LED structure to be predicted into the prediction model, thereby obtaining prediction values of output feature parameters of the LED structure to be predicted.

2. The method for predicting performance of LED structure as claimed in claim 1, wherein the input feature parameters of the LED structures comprise structures of barrier layers of quantum well regions of the LED structures, compositions of the barrier layers of the quantum well regions of the LED structures, contents of the barrier layers of the quantum well regions of the LED structures, structures of potential well layers of the quantum well regions of the LED structures, compositions of the potential well layers of the quantum well regions of the LED structures, contents of the potential well layers of the quantum well regions of the LED structures, structures of electron blocking layers of the LED structures, compositions of the electron blocking layers of the LED structures, and contents of the electron blocking layers of the LED structures; the output feature parameters corresponding to the input feature parameters comprise internal quantum efficiency of the LED structures, optical output power of the LED structures, and current densities corresponding to the optical output powers of the LED structures.

3. The method for predicting performance of LED structure as claimed in claim 1, wherein the machine learning algorithm comprises at least one selected from the group consisting of a deep learning algorithm, a multilayer perceptron algorithm, a decision tree algorithm, a linear regression algorithm, and a gradient boosting regression algorithm.

4. The method for predicting performance of LED structure as claimed in claim 3, wherein the deep learning algorithm comprises at least one selected from the group consisting of a convolutional neural network algorithm, a recurrent neural network algorithm, an auto encoder algorithm, and a deep belief network algorithm.

5. The method for predicting performance of LED structure as claimed in claim 1, wherein the LED structures are same in type, and each of the LED structures is one type selected from the group consisting of an InGaN-based visible light LED, a AlGaN-based deep ultraviolet LED, a GaAs-based LED, a GaAlAs-based LED, and a GaP-based LED.

6. The method for predicting performance of LED structure as claimed in claim 1, wherein the input feature parameters of the LED structures and the output feature parameters corresponding to the input feature parameters are screened and adjusted based on types of the LED structures.

7. The method for predicting performance of LED structure as claimed in claim 1, wherein the preprocessing the original dataset and the testing dataset comprises:
selecting parameters: selecting the input feature parameters of the LED structures based on known physical knowledge and relationships among the data, thereby obtaining selected feature parameters;
data processing: normalizing the selected input feature parameters to obtain processed feature parameters;
data restructuring: restructuring sizes of the processed feature parameters to obtain the preprocessed dataset and the preprocessed testing dataset.

8. The method for predicting performance of LED structure as claimed in claim 7, wherein a mean value of the processed feature parameters is 0 and a standard deviation of the processed feature parameters is 1 after the selected feature parameters are normalized.

9. The method for predicting performance of LED structure as claimed in claim 1, wherein the optimizing the initialized model further comprises:
evaluating a training result of the initialized model by using a mean square error;
wherein a formula of the mean square error is expressed as:
$$M S E = \frac{{\sum }_{i = 1}^{N} {( {Predict}_{i} - {Actual}_{i} )}^{2}}{N} ,$$
where Predictᵢ represents a prediction value of an i-th sample, Actualᵢ represents an actual value of the i-th sample, and N represents the total number of samples.

10. The method for predicting performance of LED structure as claimed in 1, further comprising:
adjusting a design scheme of the LED structure to be predicted based on the prediction values of the output feature parameters of the LED structure to be predicted.
